(19) United States
(12) Patent Application Publication
(10) Pub. No.: US 2021/0261804 A1
(43) Pub. Date: Aug. 26, 2021

(54) RESIN SOLUTION FOR PRINTING AND PRODUCTION METHOD FOR DEVICE STRUCTURE

(71) Applicant: ZEON CORPORATION, Tokyo (JP)

(72) Inventor: Hiroyasu INOUE, Tokyo (JP)

(73) Assignee: Zeon Corporation, Tokyo (JP)

(21) Appl. No.: 17/053,791

(22) PCT Filed: Apr. 24, 2019
(86) PCT No.: PCT/JP2019/017406

§ 371 Date: Nov. 9, 2020

(30) Foreign Application Priority Data
May 18, 2018 (JP) 2018-096374
Aug. 17, 2018 (JP) 2018-153631

(51) Int. Cl. C09D 11/36; C09D 11/108; C09D 11/033; B41M 5/00; H01L 27/32; H01L 51/00; H01L 51/52; H01L 51/56

(52) U.S. Cl. CPC C09D 11/36; C09D 11/108; C09D 11/033; B41M 5/0023; H01L 2251/5338; H01L 51/0097; H01L 51/5253; H01L 51/56; H01L 27/323

(57) ABSTRACT

A resin solution for printing including a nonpolar solvent; and a thermoplastic elastomer having a silicon atom-containing polar group, the thermoplastic elastomer being dissolved in the nonpolar solvent, wherein the resin solution has a viscosity of 1 cP or higher and 5000 cP or lower; and a method for producing a device structure body using the same. The viscosity of the resin solution for printing is preferably 1 cP or higher and 1000 cP or lower. The thermoplastic elastomer is preferably a hydrogenated aromatic vinyl compound-conjugated diene copolymer. The resin solution for printing preferably contains a hygroscopic particle, and a dispersant dissolved in the nonpolar solvent.

### FIELD

The present invention relates to a resin solution for printing and a method for producing a device structure body using the same.

### BACKGROUND

Devices such as organic electroluminescent devices and flexible touch sensors are sometimes required to include a component for preventing the intrusion of moisture into the devices.

For example, an organic electroluminescent device may include a substrate such as a glass plate and a conductor layer such as an electrode and a light-emitting layer disposed thereon. Since the conductor layer of the organic electroluminescent device deteriorates due to the intrusion of moisture, the intrusion of moisture into the conductor layer is required to be blocked. As a component having such a function, a sealing film may be used. As the sealing film, a film made of a material containing a resin and a hygroscopic particle may be used. Various sealing films and materials constituting the sealing films have been known (for example, Patent Literatures 1 to 2).

### CITATION LIST

### Patent Literature

Patent Literature 1: International Publication No. 2017/111138 (Corresponding Publication: U.S. Patent Application Publication No. 2019/006623)

Patent Literature 2: Japanese Patent Application Laid-Open No. 2017-117721 A

### SUMMARY

### Technical Problem

When sealing is performed with a sealing film, there sometimes occurs insufficiency in sealing around the display surface of the device. Although the sealing performance around the device may be improved by widening the width of the peripheral region of a device, the width of the peripheral region of the device needs to be narrow due to design requirements. In particular, since small-sized mobile devices such as a tablet and a smartphone are required to have a large-sized display screen on a small-sized device, such devices are particularly demanded to have a peripheral region narrowed.

Therefore, an object of the present invention is to provide: a material for sealing, which can achieve sealing with high sealing performance around the display surface in a device such as an organic electroluminescent device or a flexible touch sensor, even when the peripheral region is narrow; and a method for producing a device or a component thereof capable of achieving such sealing.

### Solution to Problem

The present inventor conducted research for solving the aforementioned problem. As a result, the present inventor has found that the aforementioned problem can be solved by adopting a material having specific components and physical properties as a material for forming an organic barrier layer for sealing, and disposing an organic barrier layer to a device by a method including a process of performing printing with the material. As a result, the present invention has been accomplished.

That is, the present invention is as follows.
(1) A resin solution for printing comprising:

a nonpolar solvent; and

a thermoplastic elastomer having a silicon atom-containing polar group, the thermoplastic elastomer being dissolved in the nonpolar solvent, wherein

the resin solution has a viscosity of 1 cP or higher and 5000 cP or lower.

(2) The resin solution for printing according to (1), wherein the viscosity is 1 cP or higher and 1000 cP or lower.
(3) The resin solution for printing according to (1) or (2), wherein the thermoplastic elastomer is a hydrogenated aromatic vinyl compound-conjugated diene copolymer.
(4) The resin solution for printing according to any one of (1) to (3), further comprising a hygroscopic particle.
(5) The resin solution for printing according to any one of (1) to (4), further comprising a dispersant dissolved in the nonpolar solvent.
(6) A method for producing a device structure body comprising:

forming, by printing, a layer of the resin solution for printing according to any one of (1) to (5) on a multilayer product including a substrate and a conductor layer disposed on a surface of the substrate;

drying the layer of the resin solution for printing to form an organic barrier layer; and

forming an inorganic barrier layer on a top surface side of the organic barrier layer.
(7) The method for producing a device structure body according to (6), wherein the inorganic barrier layer is a layer made of a material containing a silicon atom or an aluminum atom.

### Advantageous Effects of Invention

According to the resin solution for printing of the present invention, sealing with high sealing performance around the display surface in a device such as an organic electroluminescent device or a flexible touch sensor can be achieved even when the peripheral region is narrow. With the method for producing a device structure body of the present invention, a device or a component thereof capable of achieving such sealing can be easily produced.

### BRIEF DESCRIPTION OF DRAWINGS

FIG. 1 is a cross-sectional view schematically illustrating an example of a device structure body produced by the method for producing a device structure body according to the present invention.

FIG. 2 is a top view illustrating a planar shape and a layout of each layer in an example of the present application.

FIG. 3 is a top view illustrating a planar shape and a layout of each layer in an example of the present application.

FIG. 4 is a top view illustrating a planar shape and a layout of each layer in an example of the present application.

### DESCRIPTION OF EMBODIMENTS

Hereinafter, the present invention will be described in detail with reference to embodiments and examples. However, the present invention is not limited to the following embodiments and examples, and may be freely modified for implementation without departing from the scope of claims of the present invention and the scope of their equivalents.

In the following description, “(meth)acryl-” is the term encompassing “acryl-”, “methacryl-”, and a combination thereof, unless otherwise specified. For example, a “(meth)acrylic acid alkyl ester” means an acrylic acid alkyl ester, a methacrylic acid alkyl ester or a mixture thereof.

For convenience of explanation, the term “solvent” in the following description encompasses not only a medium in a solution but also a dispersion medium in which a solid matter is to be dispersed.

[1. Summary of Resin Solution for Printing]

The resin solution for printing according to the present invention includes a nonpolar solvent and a thermoplastic elastomer having a silicon atom-containing polar group.

[2. Nonpolar Solvent]

In many cases of forming an organic barrier layer using the resin solution for printing, the subject on which such an organic barrier layer is disposed has low durability to a polar solvent such as water. In particular, in a case of a resin solution for printing which contains a large amount of a solvent, damage to the subject on which an organic barrier layer is to be disposed can be particularly effectively reduced by adopting the nonpolar solvent as a solvent. In addition, by the adoption of the nonpolar solvent, a proportion of moisture entering the system can be easily reduced. As a result, an organic barrier layer having a favorably maintained hygroscopic performance can be easily formed with the resin solution for printing.

Examples of the substances constituting the nonpolar solvent may include a substance which is liquid at ordinary temperature (preferably 25° C.), the substance being other than water and an inorganic substance. More specifically, hydrocarbon solvents may be mentioned, and examples thereof may include cyclohexane, methylcyclohexane, ethylcyclohexane, hexane, toluene, benzene, xylene, decahydronaphthalene, trimethylbenzene, cyclooctane, cyclodecane, normal octane, dodecane, tridecane, tetradecane, cyclododecane, and mixtures thereof. As the nonpolar solvent, it is preferable to include a solvent having a boiling point of 90° C. or higher, and more preferably, a solvent having a boiling point of 100° C. or higher, in order to make the surface after drying smooth and free from unevenness. The upper limit of the boiling point of such a high boiling point solvent is not particularly limited, and may be, for example, 250° C. or lower. When the non-polar solvent includes such a high boiling point solvent, the ratio thereof may be set to fall within a specific range. For example, the ratio of the solvent having a boiling point of 100° C. or higher is preferably 10% by weight or more, and more preferably 25% by weight or more, and is preferably 60% by weight or less. In addition, cyclohexane, methylcyclohexane, and ethylcyclohexane are particularly preferable from the viewpoint of high solubility of the thermoplastic elastomer having a silicon atom-containing polar group.

The resin solution for printing may contain a polar solvent as an optional component in addition to the nonpolar solvent as long as the advantageous effects of the present invention is not significantly impaired. For example, the resin solution for printing may contain a polar solvent that is well compatible with a nonpolar solvent. More specifically, the resin solution for printing may contain a substance that may be used as a polar solvent, such as N,N-dimethylformamide or tetrahydrofuran. However, it is preferable that the solvent does not contain water as the polar substance in order to form an organic barrier layer having good performances as a sealing layer. The ratio of the nonpolar solvent in the total of the nonpolar solvent and the polar solvent is preferably 95% by weight or more, more preferably 99% by weight or more, still more preferably 99.9% by weight or more, and ideally 100% by weight.

[3. Thermoplastic Elastomer]

A thermoplastic elastomer refers to a material that exhibits rubber properties at normal temperature and can be plasticized for enabling molding at high temperature. Such a thermoplastic elastomer has a property of low tendency to cause elongation or breakage with a small load. Specifically, the thermoplastic elastomer exhibits a Young's modulus of 0.001 to 1 GPa and a tensile elongation (break elongation) of 100 to 1000% at 23° C. Further, in a high temperature range of 40° C. or higher and 200° C. or lower, the storage modulus of the thermoplastic elastomer rapidly decreases so that the loss tangent tan δ (loss modulus/storage modulus) has a peak or exhibits a value more than 1, and the thermoplastic elastomer softens. The Young's modulus and tensile elongation may be measured in accordance with JIS K7113. The loss tangent tano may be measured by a commercially available dynamic viscoelasticity measuring device.

In general, a thermoplastic elastomer contains no or little, if any, residual solvent. Therefore, a thermoplastic elastomer has an advantage that the amount of outgas is small. Furthermore, a thermoplastic elastomer has an advantage that sealing can be performed in a simple process without crosslinking treatment or the like.

The thermoplastic elastomer used in the present invention is a thermoplastic elastomer having a silicon atom-containing polar group. The adoption of the thermoplastic elastomer having a silicon-containing polar group can improve adhesion strength with another member.

In the resin solution for printing, the thermoplastic elastomer having a silicon atom-containing polar group exists in a dissolved state. In the resin solution for printing, the thermoplastic elastomer having a silicon atom-containing polar group can exist as dissolved solid contents. The solid contents in the resin solution for printing are components other than the solvent and usually all the components that remain after the resin solution for printing is dried to volatilize the solvent.

As the thermoplastic elastomer having a silicon atom-containing polar group, a polymer having a silicon atom-containing polar group can be adopted. The polymer having a silicon atom-containing polar group is a polymer obtained by a reaction to cause linkage of a certain polymer with a compound having a silicon atom-containing polar group. However, the polymer having a silicon atom-containing polar group is not limited by the production method thereof. In the following description, a polymer used for such a reaction is referred to as a “pre-reaction polymer” for distinction from a polymer contained in the resin solution for printing according to the present invention.

[3.1. Pre-Reaction Polymer]

Examples of the pre-reaction polymer may include an ethylene-α-olefin copolymer such as an ethylene-propylene copolymer; an ethylene-α-olefin-polyene copolymer; a copolymer of ethylene and an unsaturated carboxylic acid ester such as ethylene-methyl methacrylate and ethylene-butyl acrylate; a copolymer of ethylene with a vinyl fatty acid, such as ethylene-vinyl acetate; an acrylic acid alkyl ester polymer such as ethyl acrylate, butyl acrylate, hexyl acrylate, 2-ethylhexyl acrylate, and lauryl acrylate; a diene-based copolymer such as polybutadiene, polyisoprene, an acrylonitrile-butadiene copolymer, a butadiene-isoprene copolymer, a butadiene-(meth)acrylic acid alkyl ester copolymer, a butadiene-(meth)acrylic acid alkyl ester-acrylonitrile copolymer, and a butadiene-(meth)acrylic acid alkyl ester-acrylonitrile-styrene copolymer; a butylene-isoprene copolymer; an aromatic vinyl compound-conjugated diene copolymer such as a styrene-butadiene random copolymer, a styrene-isoprene random copolymer, a styrene-butadiene block copolymer, a styrene-butadiene-styrene block copolymer, a styrene-isoprene block copolymer, and a styrene-isoprene-styrene block copolymer; a hydrogenated aromatic vinyl compound-conjugated diene copolymer such as a hydrogenated styrene-butadiene random copolymer, a hydrogenated styrene-isoprene random copolymer, a hydrogenated styrene-butadiene block copolymer, a hydrogenated styrene-butadiene-styrene block copolymer, a hydrogenated styrene-isoprene block copolymer, and a hydrogenated styrene-isoprene-styrene block copolymer; and low crystallizable polybutadiene, a styrene-grafted ethylene-propylene elastomer, a thermoplastic polyester elastomer, and an ethylene-based ionomer. As these polymer, one type thereof may be solely used, and two or more types thereof may also be used in combination at any ratio.

As the polymer, a polymer selected from an aromatic vinyl compound-conjugated diene copolymer, a hydrogenated aromatic vinyl compound-conjugated diene copolymer, and a combination thereof is preferable for obtaining desired advantageous effects of the present invention.

As the aromatic vinyl compound-conjugated diene copolymer, an aromatic vinyl compound-conjugated diene block copolymer is preferable. As the aromatic vinyl compound, styrene and a derivative thereof, or vinylnaphthalene and a derivative thereof are preferable, and styrene is particularly preferably used because of industrial availability. As the conjugated diene, a chain conjugated diene (linear conjugated diene, branched conjugated diene) is preferable, and specific examples thereof may include 1,3-butadiene, isoprene (2-methyl-1,3-butadiene), 2,3-dimethyl-1,3-butadiene, and 1,3-pentadiene. Of these, 1,3-butadiene and isoprene are particularly preferable because of industrial availability.

As the aromatic vinyl compound-conjugated diene block copolymer, an aromatic vinyl compound-conjugated diene block copolymer is preferably selected from a styrene-butadiene block copolymer, a styrene-butadiene-styrene block copolymer, a styrene-isoprene block copolymer, a styrene-isoprene-styrene block copolymer, and mixtures thereof.

The hydrogenated aromatic vinyl compound-conjugated diene copolymer is a hydrogenated product of an aromatic vinyl compound-conjugated diene copolymer. That is, the hydrogenated aromatic vinyl compound-conjugated diene copolymer has a structure obtained by hydrogenating a part or all of carbon-carbon unsaturated bonds of a main chain and a side chain of an aromatic vinyl compound-conjugated diene copolymer, carbon-carbon bonds of the aromatic ring, or both. However, the hydrogenated product in the present application is not limited by the production method thereof.

The hydrogenation ratio of the hydrogenated aromatic vinyl compound-conjugated diene copolymer is preferably 90% or more, more preferably 97% or more, and particularly preferably 99% or more. The higher the hydrogenation rate, the better the heat resistance and light resistance of the organic barrier layer. Herein, the hydrogenation rate of the hydrogenated product may be determined by measurement by means of ¹H-NMR.

The hydrogenation ratio of the carbon-carbon unsaturated bonds of the main chain and the side chain of the hydrogenated aromatic vinyl compound-conjugated diene copolymer is preferably 95% or more, and more preferably 99% or more. By increasing the hydrogenation rate of the carbon-carbon unsaturated bonds of the main chain and the side chain of the hydrogenated aromatic vinyl compound-conjugated diene copolymer, the light resistance and the oxidation resistance of the organic barrier layer can be further increased.

The hydrogenation ratio of the carbon-carbon unsaturated bonds of the aromatic ring of the hydrogenated aromatic vinyl compound-conjugated diene copolymer is preferably 90% or more, more preferably 93% or more, and particularly preferably 95% or more. By increasing the hydrogenation rate of the carbon-carbon unsaturated bonds of the aromatic ring, the glass transition temperature of the hydrogenated product increases, so that the heat resistance of the organic barrier layer can be effectively increased. In addition, the photoelastic modulus of the organic barrier layer can be lowered to reduce the occurrence of retardation.

As the hydrogenated aromatic vinyl compound-conjugated diene copolymer, a hydrogenated aromatic vinyl compound-conjugated diene block copolymer is preferable. The hydrogenated aromatic vinyl compound-conjugated diene block copolymer is preferably selected from a hydrogenated styrene-butadiene block copolymer, a hydrogenated styrene-butadiene-styrene block copolymer, a hydrogenated styrene-isoprene block copolymer, a hydrogenated styrene-isoprene-styrene block copolymer, and mixtures thereof. More specific examples thereof may include those described in prior art literatures such as Japanese Patent Application Laid-Open No. Hei. 2-133406 A, Japanese Patent Application Laid-Open No. Hei. 2-305814 A, Japanese Patent Application Laid-Open No. Hei. 3-72512 A, Japanese Patent Application Laid-Open No. Hei. 3-74409 A, and International Publication No. 2015/099079.

As the hydrogenated aromatic vinyl compound-conjugated diene block copolymer, those having a structure obtained by hydrogenating both the unsaturated bonds derived from the conjugated diene and the aromatic ring are preferable.

Examples of the particularly preferable block form of the hydrogenated aromatic vinyl compound-conjugated diene block copolymer may include a triblock copolymer obtained by bonding blocks [A] of a hydrogenated product of an aromatic vinyl polymer to both ends of a block [B] of a hydrogenated product of a conjugated diene polymer; and a pentablock copolymer obtained by bonding polymer blocks [B] to both ends of a polymer block [A] and then further bonding polymer blocks [A] to the respective other ends of both polymer blocks [B]. In particular, the triblock copolymer of [A]-[B]-[A] is particularly preferable because of easy production process thereof and capability to exhibit a desired range of properties as a thermoplastic elastomer.

The ratio (wA:wB) of wA to wB is preferably 20/80 or more, and more preferably 30/70 or more, and is preferably 60/40 or less, and more preferably 55/45 or less, when the total weight fraction of the aromatic vinyl monomer unit in the entire block copolymer is defined as wA and the total weight fraction of the conjugated diene monomer unit in the entire block copolymer is defined as wB. By setting the ratio wA/wB to be equal to or higher than the lower limit value of the foregoing range, the heat resistance of the organic barrier layer can be improved. In addition, by setting the ratio to be equal to or less than the upper limit value, the flexibility of the organic barrier layer can be enhanced, and the barrier property of the organic barrier layer can be stably and satisfactorily maintained. Further, the glass transition temperature of the block copolymer can be lowered and thereby the sealing temperature can be lowered, whereby, when the resin solution for printing of the present invention is applied to an organic electroluminescent device, an organic semiconductor device, or the like, thermal degradation of the device can be suppressed. In addition, by setting the ratio (wA/wB) to fall within the foregoing range, the temperature range in which the organic barrier layer has a rubber elasticity can be widened, and the temperature range in which the device has flexibility can be widened.

[3.2. Compound Having a Silicon Atom-Containing Polar Group]

The polymer having a silicon atom-containing polar group may be a graft polymer. The graft polymer having a silicon atom-containing polar group is a polymer having a structure obtained by graft polymerization of a pre-reaction polymer and a compound having a silicon atom-containing polar group as a monomer. However, the graft polymer having a silicon atom-containing polar group is not limited by the production method thereof. As the silicon atom-containing polar group, an alkoxysilyl group is preferable.

Examples of compounds having a silicon atom-containing polar group that may be used as a monomer for graft polymerization may include ethylenically unsaturated silane compounds having an alkoxysilyl group such as vinyltrimethoxysilane, vinyltriethoxysilane, allyltrimethoxysilane, allyltriethoxysilane, dimethoxymethylvinylsilane, diethoxymethylvinylsilane, p-styryltrimethoxysilane, p-styryltriethoxysilane, 3-methacryloxypropyltrimethoxysilane, 3-methacryloxypropylmethyldimethoxysilane, 3-methacryloxypropyltriethoxysilane, 3-methacryloxypropylmethyldiethoxysilane, 3-acryloxypropyltrimethoxysilane, 3-acryloxypropyltriethoxysilane, and 2-norbornen-5-yltrimethoxysilane.

By the reaction of the pre-reaction polymer with a compound having a silicon atom-containing polar group, a silicon atom-containing polar group can be introduced into the pre-reaction polymer to obtain a polymer having a silicon atom-containing polar group. When an alkoxysilyl group is introduced as a silicon atom-containing polar group, the amount of the alkoxysilyl group to be introduced is usually 0.1 part by weight or more, preferably 0.2 part by weight or more, and more preferably 0.3 part by weight or more, and is usually 10 parts by weight or less, preferably 5 parts by weight or less, and more preferably 3 parts by weight or less, relative to 100 parts by weight of the pre-reaction polymer. By confining the amount of the alkoxysilyl group to be introduced within the foregoing range, the crosslinking degree between the alkoxysilyl groups decomposed by moisture or the like can be prevented from becoming excessively high, so that it is possible to maintain high adhesiveness. Examples of the substance having an alkoxysilyl group used for introducing an alkoxysilyl group and the modification method may include those described in prior art literatures such as International Publication No. 2015/099079.

The introduction amount of the polar group may be measured by a ¹H-NMR spectrum. When the introduction amount of the polar group is small, the introduction amount may be measured by increasing the number of integrations.

The introduction of the alkoxysilyl group as the polar group to the pre-reaction polymer is called silane modification. Upon the silane modification, an alkoxysilyl group may be directly bonded to the pre-reaction polymer. Alternatively, for example, an alkoxysilyl group may be bonded via a divalent organic group such as an alkylene group. Hereinafter, a polymer obtained by the silane modification of the pre-reaction polymer may be referred to as a “silane-modified polymer”.

As the silane-modified polymer, one or more types of polymers selected from a silane-modified product of a hydrogenated styrene-butadiene block copolymer, a silane-modified product of a hydrogenated styrene-butadiene-styrene block copolymer, a silane-modified product of a hydrogenated styrene-isoprene block copolymer, and a silane-modified product of a hydrogenated styrene-isoprene-styrene block copolymer are preferable.

The weight-average molecular weight (Mw) of the polymer having a silicon atom-containing polar group is usually 20000 or more, preferably 30000 or more, and more preferably 35000 or more, and is usually 200000 or less, preferably 100000 or less, and more preferably 70000 or less. The weight-average molecular weight of the polymer may be measured as a polystyrene-equivalent value by gel permeation chromatography using tetrahydrofuran as a solvent. The molecular weight distribution (Mw/Mn) of the polymer is preferably 4 or less, more preferably 3 or less, and particularly preferably 2 or less, and is preferably 1 or more. By confining the weight-average molecular weight Mw and the molecular weight distribution Mw/Mn of the polymer within the foregoing ranges, the mechanical strength and the heat resistance of the organic barrier layer formed by the resin solution for printing can be improved.

[3.3. Other Characteristics of Thermoplastic Elastomer]

The glass transition temperature of the thermoplastic elastomer having a silicon atom-containing polar group is not particularly limited, and is preferably 40° C. or higher, and more preferably 70° C. or higher, and is usually 200° C. or lower, preferably 180° C. or lower, and more preferably 160° C. or lower. When a thermoplastic elastomer containing a block copolymer is used as the thermoplastic elastomer having a silicon atom-containing polar group, it is possible to balance the adhesiveness at the time of sealing a device and the flexibility after sealing. Such balancing can be achieved by changing the weight ratio of the respective polymer blocks to adjust the glass transition temperature.

The ratio of the thermoplastic elastomer having a silicon atom-containing polar group in the resin solution for printing of the present invention is not particularly limited, and may be appropriately adjusted within a range in which desired properties such as viscosity suitable for the purpose of use can be obtained. Specifically, the ratio of the thermoplastic elastomer having a silicon atom-containing polar group in the total amount of the resin solution for printing is preferably 1% by weight or more, and more preferably 3% by weight or more, and is preferably 40% by weight or less, more preferably 30% by weight or less, and still more preferably 20% by weight or less.

[4. Optional Component: Hygroscopic Particle]

The resin solution for printing may include, in addition to the polymer, an optional component. Examples of the optional component may include hygroscopic particles.

In the resin solution for printing and the organic barrier layer as a cured product thereof, the hygroscopic particles exist in a dispersed state. The primary particle diameter of the hygroscopic particles is preferably 30 nm or more, and more preferably 40 nm or more, and is preferably 150 nm or less, and more preferably 80 nm or less. The refractive index (value measured at a wavelength of 589 nm; the same applies hereinafter) of the hygroscopic particles is preferably 1.2 or more and 3.0 or less. When such hygroscopic particles are used together with a specific dispersant, there can be obtained an organic barrier layer having properties of high transparency and high surface smoothness as well as low haze. The haze of the cured product constituting the organic barrier layer is preferably 1.0% or less, more preferably 0.3% or less, and further preferably 0.1% or less. The haze is usually 0% or more. The haze of the cured product herein is a value measured on a sample obtained by molding the cured product into a film having a thickness of 10 μm. The haze may be measured by a turbidimeter.

In the present application, the primary particle diameter represents the number-average particle diameter of primary particles. The primary particle diameter (number-average particle diameter) of the hygroscopic particles may be measured in the state of a dispersion liquid in which particles are dispersed in a solvent, by a particle diameter measuring device in accordance with a dynamic light scattering method. As another method, the measurement may be performed by shaping the measurement subject into a film, directly observing particles on the cross section of the film through an electron microscope, and calculating an average value of particle diameters.

The hygroscopic particle is a particle of which the weight change ratio when left to stand at 20° C. and 90% RH for 24 hours is as high as a specific value or more.

The specific range of the weight change ratio is usually 3% or more, preferably 10% or more, and more preferably 15% or more. The upper limit of the weight change ratio is not particularly limited, and may be, for example, 100% or less. With the hygroscopic particle having such high hygroscopicity, sufficient moisture absorption can be achieved even with a small amount thereof, and thereby a favorable hygroscopic effect can be achieved with a small containing ratio. As a result, inhibition of rubber properties originated by the thermoplastic elastomer having a silicon atom-containing polar group can be advantageously avoided.

The weight change ratio of the hygroscopic particle may be calculated according to the following formula (A1). In the following formula (A1), W1 represents the weight of particles before left to stand under an environment of 20° C. and 90% Rh, and W2 represents the weight of particles after left to stand under an environment of 20° C. and 90% Rh for 24 hours.

Weight change ratio (%)=((W2−W1)/W1)×100 (A1)

Examples of a material contained in the hygroscopic particles may include: a basic moisture absorbent such as a compound (oxide, hydroxide, salt, or the like) that contains alkali metal, alkali earth metal, and aluminum and does not contain silicon (for example, barium oxide, magnesium oxide, calcium oxide, strontium oxide, aluminum hydroxide, and hydrotalcite), an organic metal compound disclosed in Japanese Patent Application Laid-Open No. 2005-298598 A, and a metal oxide-containing clay; and an acidic moisture absorbent such as a silicon-containing inorganic compound (for example, silica gel, nanoporous silica, zeolite).

As the material of the hygroscopic particle, one or more substances selected from the group consisting of zeolite and hydrotalcite are preferable. Zeolite has an especially high moisture absorption ability. For example, zeolite can easily achieve a high weight change ratio of 10% to 30% when left to stand at 20° C. and 90% RH for 24 hours. Also, as zeolite releases water when being dried, zeolite is recyclable. As the material of the hygroscopic particles, one type thereof may be solely used, and two or more types thereof may also be used in combination at any ratio.

The ratio of the hygroscopic particles in the resin solution for printing according to the present invention is preferably 5% by weight or more, and more preferably 10% by weight or more, and is preferably 60% by weight or less, preferably 40% by weight or less, and more preferably 30% by weight or less, relative to the total amount of the solid content. When the ratio of the hygroscopic particles is equal to or more than the aforementioned lower limit value, the moisture intrusion prevention effect of the organic barrier layer can be improved. Also, when equal to or less than the aforementioned upper limit value, a desired property such as transparency of the organic barrier layer can be improved.

[5. Optional Component: Dispersant]

A further example of the optional component of the resin solution for printing according to the present invention may be a dispersant.

In the resin solution for printing, it is preferable that the manner of existence of the dispersant is in a state of being dissolved in the nonpolar solvent. Therefore, the dispersant is preferably soluble in the nonpolar solvent. Specifically, a dispersant capable of achieving dissolution of 5% by weight or more in the nonpolar solvent is preferable. Such dissolution may be tested at a temperature at which the resin solution for printing is prepared. The temperature is usually normal temperature (5° C. to 35° C.), and preferably 25° C.

When the nonpolar solvent-soluble dispersant is used as the dispersant, the resin solution for printing can be produced by a production method in which water is not used. As a result, an organic barrier layer having favorable performance as an organic barrier layer for blocking the intrusion of moisture can be easily produced.

In the resin solution for printing and the organic barrier layer, the dispersant has a function of improving the dispersibility of the hygroscopic particles.

Examples of the dispersant may include commercially available dispersants such as “ARON®” and “JURYMER®” series of Toagosei Co., Ltd., “AQUALIC®” series) of Nippon Shokubai Co., Ltd., “FLOWLEN®” series of Kyoeisha Chemical Co., Ltd., “DISPARLON®” series of Kusumoto Chemicals, Ltd., “SOKALAN®” series and “EFKA” series of BASF SE, “DISPERBYK®” series and “Anti-Terra” series of BYK-Chemie, “SOLSPERSE®” series of The Lubrizol Corporation, and “AJISPER” series of Ajinomoto Fine-Techno Co., Inc.

The dispersant may be an agent having a group that adsorbs to the hygroscopic particles and a group that influences interaction and compatibility between a resin and a dispersant.

Examples of a group that adsorbs to the hygroscopic particles may include an amino group, a carboxyl group, a phosphoric acid group, an amine salt, a carboxylic acid salt, a phosphoric acid salt, an ether group, a hydroxyl group, an amido group, an aromatic vinyl group, and an alkyl group. When the hygroscopic particle is an acidic hygroscopic particle, an adsorbing group is preferably basic (a basic dispersant). When the hygroscopic particle is a basic hygroscopic particle, an adsorbing group is preferably acidic (an acidic dispersant). However, the dispersant may be nonionic.

The lower limit value of the acid number or basic number (amine number) of the dispersant is preferably 20 mgKOH/g or more, and more preferably 50 mgKOH/g or more. The upper limit value of the acid number or basic number is preferably 200 mgKOH/g or less, and more preferably 160 mgKOH/g or less. When a dispersant having an acid number or basic number (amine number) in these ranges is selected, particles can be efficiently dispersed in a short period of time.

Examples of a group that influences interaction and compatibility between a resin and a dispersant may include fatty acid, polyamino, polyether, polyester, polyurethane, and polyacrylate.

Also, a silane coupling agent manufactured by Shin-Etsu Silicone Co., Ltd. or Dow Corning Toray Co., Ltd., for example, may be used as the dispersant. As to a case of a silane coupling agent, a portion to adsorb to the hygroscopic particle is referred to as a hydrolyzable group, and a portion to influence interaction and compatibility between a resin and a solvent is referred to as a reactive functional group. Examples of the hydrolyzable group may include —OCH₃, —OC₂H₅, and —OCOCH₃. On the other hand, examples of the reactive functional group may include an amino group, an epoxy group, a methacryl group, and a vinyl group. As such a dispersant, one type thereof may be solely used, and two or more types thereof may also be used as a mixture.

The amount of the dispersant is preferably 0.1 part by weight or more, more preferably 7 parts by weight or more, and further more preferably 10 parts by weight or more, and is preferably 1000 parts by weight or less, more preferably 70 parts by weight or less, and further more preferably 50 parts by weight or less, relative to 100 parts by weight of the hygroscopic particles. When the amount of the dispersant is equal to or more than the aforementioned lower limit value, favorable dispersion of the hygroscopic particle can be achieved, and the internal haze of the organic barrier layer can be lowered to achieve high transparency. When the amount of the dispersant is equal to or less than the aforementioned upper limit value, the reduction in adhesion between the organic barrier layer and another member attributable to the dispersant can be suppressed.

[6. Optional Component: Plasticizer]

A further example of the optional component of the printing resin solution of the present invention may be a plasticizer. When a plasticizer is contained, the organic barrier layer can be a layer in which properties such as the glass transition temperature and the elastic modulus are adjusted to respective desired values.

Suitable examples of the plasticizer may include a hydrocarbon-based oligomer; an organic acid ester-based plasticizer such as a monobasic organic acid ester, and a polybasic organic acid ester; a phosphoric acid ester-based plasticizer such as an organophosphate ester-based plasticizer and an organophosphite ester-based plasticizer; and combinations thereof.

It is preferable that the hydrocarbon-based oligomer is one which can be uniformly dissolved or dispersed in the resin solution for printing. It is preferable that the hydrocarbon-based oligomer is a polymer of a hydrocarbon compound and has a molecular weight within a specific range because it does not significantly impair heat resistance and is dispersed well in the resin solution for printing. The molecular weight of the hydrocarbon-based oligomer is preferably 200 to 5000, more preferably 300 to 3000, and still more preferably 500 to 2000, as a number-average molecular weight.

Specific examples of the hydrocarbon-based oligomer may include a polyisobutylene, a polybutene, a poly-4-methylpentene, a poly-1-octene, an ethylene-α-olefin copolymer, a polyisoprene, an alicyclic hydrocarbon, other aliphatic hydrocarbons, an aromatic vinyl compound-conjugated diene copolymer, hydrogenated products of the aforementioned compounds, and a hydrogenated product of an indene-styrene copolymer. Among these, a polyisobutylene, a polybutene, a hydrogenated polyisobutylene, and a hydrogenated polybutene are preferable.

The amount of the plasticizer is preferably 1 part by weight or more, more preferably 5 parts by weight or more, and still more preferably 10 parts by weight or more, and is preferably 60 parts by weight or less, and more preferably 50 parts by weight or less, relative to 100 parts by weight of the thermoplastic elastomer having a silicon atom-containing polar group. When the amount of the plasticizer is equal to or more than the lower limit, a sufficient plasticizing effect can be obtained, and lamination at a low temperature can be facilitated. When the amount of the plasticizer is equal to or lower than the foregoing upper limit, bleed-out of the plasticizer can be suppressed, and adhesiveness between the organic barrier layer and another layer can be enhanced.

[7. Optional Component: Others]

Further examples of the optional component may include a light stabilizer for improving weather resistance and heat resistance, an ultraviolet absorber, an antioxidant, a lubricant, and an inorganic filler. As these optional components, one type thereof may be solely used, and two or more types thereof may also be used in combination at any ratio.

Examples of the antioxidant may include a phosphorus-based antioxidant, a phenol-based antioxidant, and a sulfur-based antioxidant, and a phosphorus-based antioxidant having less coloring is preferable.

Examples of the phosphorus-based antioxidant may include a monophosphite-based compound such as triphenylphosphite, diphenylisodecylphosphite, phenyldiisodecylphosphite, tris(nonylphenyl)phosphite, tris(dinonylphenyl)phosphite, tris(2,4-di-t-butylphenyl)phosphite, and 10-(3,5-di-t-butyl-4-hydroxybenzyl)-9,10-dihydro-9-oxa-10-phosphaphenanthrene-10-oxide; a diphosphite-based compound such as 4,4′-butylidene-bis(3-methyl-6-t-butylphenyl-di-tridecylphosphite) and 4,4′-isopropylidene-bis(phenyl-di-alkyl (C12 to C15) phosphite); and compounds such as 6-[3-(3-t-butyl-4-hydroxy-5-methylphenyl)propoxy]-2,4,8,10-tetrakis-t-butyldibenzo[d,f][1.3.2]dioxaphosphepine, and 6-[3-(3,5-di-t-butyl-4-hydroxyphenyl)propoxy]-2,4,8,10-tetrakis-t-butyldibenzo[d,f][1.3.2]dioxaphosphepine.

Examples of the phenol-based antioxidant may include compounds such as pentaerythritol tetrakis[3-(3,5-di-t-butyl-4-hydroxyphenyl)propionate], 2,2-thio-diethylenebis[3-(3,5-di-t-butyl-4-hydroxyphenyl)propionate], octadecyl-3-(3,5-di-t-butyl-4-hydroxyphenyl)propionate, 3,9-bis{2-[3-(3-t-butyl-4-hydroxy-5-methylphenyl)propionyloxy]-1,1-dimethylethyl}-2,4,8,10-tetraoxaspiro[5,5]undecane, and 1,3,5-trimethyl-2,4,6-tris(3,5-di-t-butyl-4-hydroxybenzyl)benzene.

Examples of the sulfur-based antioxidant may include compounds such as dilauryl-3,3′-thiodipropionate, dimyristyl-3,3′-thiodipropionate, distearyl-3,3′-thiodipropionate, laurylstearyl-3,3′-thiodipropionate, pentaerythritol-tetrakis-(β-lauryl-thio-propionate), and 3,9-bis(2-dodecylthioethyl)-2,4,8,10-tetraoxaspiro[5,5]undecane.

The amount of the antioxidant is usually 0.01 part by weight or more, preferably 0.05 part by weight or more, and more preferably 0.1 part by weight or more, and is usually 1 part by weight or less, preferably 0.5 part by weight or less, and more preferably 0.3 part by weight or less, relative to 100 parts by weight of the thermoplastic elastomer having a silicon atom-containing polar group. By using an antioxidant in an amount of a lower limit value or more of the foregoing range, durability of the organic barrier layer can be improved. It is difficult to obtain further improvement by in-excess use of the antioxidant in an amount exceeding the upper limit.

[8. Properties and Others of Resin Solution for Printing]

The resin solution for printing according to the present invention has a viscosity value within a specific range. The viscosity of the resin solution for printing is 1 cP or higher, and preferably 3 cP or higher, and is 5000 cP or lower, preferably 1000 cP or lower, more preferably 500 cP or lower, and further preferably 50 cP or lower. The viscosity may be measured using a tuning-fork vibration type viscometer (for example, SV-10 tuning-fork vibration type viscometer manufactured by A&D Company, Limited). The measurement temperature may be 25° C.±2° C.

With such a viscosity, the resin solution for printing can be suitably used for forming an organic barrier layer by printing, and sealing around a display surface can be achieved with high sealing performance even when the peripheral region is narrow. In particular, when the viscosity is 50 cP or lower, and preferably 10 cP or lower, the resin solution for printing can be suitably used for forming an organic barrier layer by ink-jet printing. Therefore the resin solution having viscosity in such a range is particularly preferable.

The ratio of the solid content (components other than the solvent) in the resin solution for printing is not particularly limited. The ratio may be appropriately adjusted in a range in which desired properties such as a viscosity suited to the use purpose can be obtained. Specifically, the ratio of the solid content in the total amount of the resin solution for printing is preferably 1% by weight or more, and more preferably 3% by weight or more, and is preferably 40% by weight or less, more preferably 30% by weight or less, and further preferably 20% by weight or less.

[9. Use Application of Resin Solution for Printing: Method for Producing Device Structure Body]

The aforementioned resin solution for printing according to the present invention may be used for the use application of sealing. Specifically, an organic barrier layer may be formed by forming a layer of the resin solution for printing on any optional member by printing and then drying the formed layer, and therewith intrusion of moisture from the outside of the organic barrier layer into the member can be prevented.

As a preferable use application, the resin solution for printing according to the present invention may be used in a method for producing a device structure body. Hereinafter, such a production method will be described as the method for producing a device structure body according to the present invention.

A “device structure body” produced by the method for producing a device structure body according to the present invention includes various optical devices and assemblies partly constituting optical devices. Specific examples of the optical devices may include a liquid crystal display device, a touch panel, and an organic electroluminescent device as a display device or a light source device.

The method for producing a device structure body according to the present invention includes the following steps.

Step (1): A step of forming, by printing, a layer of the aforementioned resin solution for printing according to the present invention on a multilayer product including a substrate and a conductor layer disposed on the surface of the substrate.

Step (2): A step of drying the layer of the resin solution for printing to form an organic barrier layer.

Step (3): A step of forming an inorganic barrier layer on the top surface of the organic barrier layer.

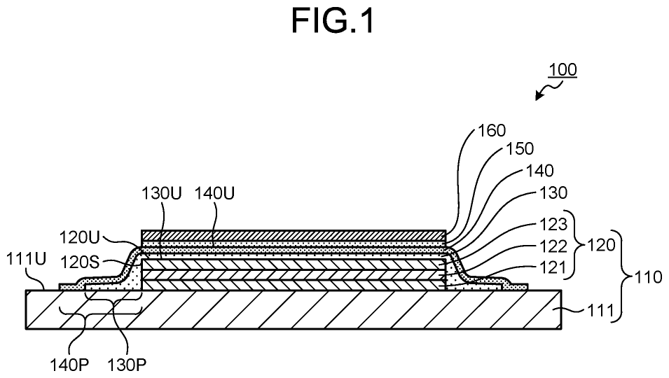

FIG. 1 is a cross-sectional view schematically illustrating an example of a device structure body produced by the method for producing a device structure body according to the present invention. Hereinafter, the method for producing a device structure body according to the present invention will be described with reference to this example.

In FIG. 1, a device structure body 100 includes a substrate 111, a conductor layer 120 disposed on a top surface 111U of the substrate 111, an organic barrier layer 130 disposed on the top surface 111U of the substrate 111 and a top surface (a surface of the conductor layer 120 facing opposite to the substrate 111 side) 120U of the conductor layer 120, an inorganic barrier layer 140 disposed on a top surface (a surface of the organic barrier layer 130 facing opposite to the conductor layer 120 side) 130U of the organic barrier layer 130, and a circular polarizing plate 160 disposed on a top surface (a surface of the inorganic barrier layer 140 facing opposite to the organic barrier layer 130 side) 140U of the inorganic barrier layer 140 through an adhesive layer 150. In this example, the device structure body 100 includes a reflective electrode layer 121, a light-emitting layer 122, and a transparent electrode 123 in this order from the lower side, as a plurality of layers constituting the conductor layer 120.

For convenience of explanation in the description of the present application, the positional relationship will be described on the presumption that the substrate is horizontally placed, and the conductor layer, the organic barrier layer, and the inorganic barrier layer are formed on the upper side surface of the substrate as illustrated in the example of FIG. 1, unless otherwise specified. Therefore, for example, as to the multilayer product containing the substrate, the conductor layer, the organic barrier layer, and the inorganic barrier layer, the “upper side” indicates the inorganic barrier layer side unless otherwise specified, and the “lower side” indicates the substrate side unless otherwise specified.

[9.1. Step (1)]

As the substrate and the conductor layer in the step (1), those known for constituting a device structure body may be appropriately adopted.

Examples of the substrate may include a glass plate, a resin plate, and a resin film. The substrate may be constituted by only a single layer or a plurality of layers. For example, the substrate may include a resin film and a barrier layer disposed on the surface thereof.

Examples of the conductor layer may include an electrode, a light-emitting layer, and a combination thereof which constitute an organic electroluminescent device, as well as a patterned wiring which constitutes a touch panel. In the present application, the term “conductor layer” encompasses those disposed on the substrate occupying a large area as well as those having any optional surface shape such as a band, a thin line, a rectangle, or dots, such as a wiring and other structure products on the substrate. The term “conductor layer” further encompasses various layers which express their functions by the movement of electron in the layers. For example, it can encompass not only a highly electroconductive layer such as metal but also an organic thin layer having a relatively low electroconductivity such as a light-emitting layer. The conductor layer may include, in its inside or on its surface, a member other than the conductor layer, such as a member configured to maintain the mechanical structure. For example, the conductor layer may contain a component member of a display element such as a liquid crystal cell or an organic electroluminescent element.

The multilayer product may have only one layer or two or more layers as a layer constituting the conductor layer. In an example illustrated in FIG. 1, the reflective electrode layer 121, the light-emitting layer 122, and the transparent electrode 123, which are layers constituting the conductor layer, are disposed in a manner such that the entirety thereof is stacked. However, the present invention is not limited thereto. When two or more layers exist as a layer constituting the conductor layer, the layers may be aligned without being overlapped on each other. Alternatively, they may be in a state such that a part or the entirety thereof are stacked.

The method for disposing the conductor layer on the substrate is not particularly limited, and any known method may be selected and adopted. For example, a method such as sputtering or vapor deposition may be performed.

In the step (1), formation of a layer of the resin solution for printing is performed by printing. Specifically, printing with the resin solution for printing is performed on a surface of the multilayer product on the side of the conductor layer, thereby forming a layer of the resin solution for printing. Specific examples of the printing operation may include screen printing and ink-jet printing.

[9.2. Step (2)]

Specific examples of the drying operation in the step (2) may include natural drying, heat drying, vacuum drying, and vacuum heat drying. When natural drying is accomplished simply by leaving the resin solution to stand at room temperature for a short period of time, a specific drying operation can become unnecessary. However, since the resin solution for printing may usually contain a large amount of a solvent in order to obtain a desired viscosity, a drying operation is usually performed.

By the step (2), the solvent is volatilized from the layer of the resin solution for printing, so that a layer of the remaining solid content can be formed as an organic barrier layer.

Explaining with reference to the example of FIG. 1, the organic barrier layer 130 is disposed by forming a layer of the resin solution for printing on the top surface (the top surface 111U of the substrate 111 and the top surface 120U of the conductor layer 120) of a multilayer product 110 including the substrate 111 and the conductor layer 120 and then drying the formed layer. In this example, the organic barrier layer 130 extends, in addition to on the top surface 120U of the conductor layer 120, in a peripheral region 130P around the conductor layer 120. As a result, a side area 120S of the conductor layer 120 is also sealed by the organic barrier layer 130. Furthermore, when the resin solution for printing has a specific viscosity, favorable sealing without any gaps is achieved in the peripheral region 130P and a region around the side area 120S of the conductor layer 120. Accordingly, compared to known sealing performed by bonding a sealing film, sealing with high sealing performance of the side area 120S can be achieved even when the width of the peripheral region 130P is narrow. As a result, the obtained device structure body can have advantageous effects such as reduction in the occurrence of failures in the outer circumferential area of the display region.

When the organic barrier layer is formed in the peripheral region, that is, in a region extending in a wider range than the region of the multilayer product to be sealed, as in the example of FIG. 1, favorable sealing can be achieved. The width of the peripheral region is preferably wide from the viewpoint of achieving effective sealing. Specifically, the width of the peripheral region is preferably 0.01 mm or more, and more preferably 0.05 mm or more. On the other hand, the width of the peripheral region needs to be narrow due to design requirements. For example, a small-sized mobile device is sometimes required to have a narrow peripheral region of preferably 0.2 mm or less, more preferably 0.1 mm or less. The adoption of the production method according to the present invention can achieve easy formation of an organic barrier layer capable of achieving effective sealing can be easily formed, even when the peripheral portion is narrow like this.

The thickness of the organic barrier layer is preferably 0.5 μm or more, more preferably 1 μm or more, and further preferably 2 μm or more, and is preferably 20 μm or less, more preferably 10 μm or less, and further preferably 5 μm or less. When the thickness of the organic barrier layer is equal to or more than the aforementioned lower limit value, effective suppression of the intrusion of moisture can be easily achieved. When the thickness of the organic barrier layer is equal to or less than the aforementioned upper limit value, the effect of reducing the thickness of the device structure body, for example, can be achieved.

The haze of the organic barrier layer according to the present invention is preferably 0.5% or less, more preferably 0.15% or less, and further preferably 0.05% or less. When the haze is equal to or less than the aforementioned range, the organic barrier layer can have a high transparency. Therefore, the organic barrier layer can be suitably used at locations where transmission of light is required in an organic electroluminescent device, a flexible touch sensor, and the like. The haze may be measured by a turbidimeter.

[9.3. Step (3)]

In the step (3), the inorganic barrier layer is usually disposed to be in direct contact with the organic barrier layer. Preferable examples of the inorganic material contained in the inorganic barrier layer to be disposed may include metal; an oxide, a nitride, and a nitride oxide of silicon; an oxide, a nitride, and a nitride oxide of aluminum; DLC (diamond-like carbon); and a material containing a mixture of two or more thereof. In particular, materials containing a silicon atom or an aluminum atom, such as an oxide, a nitride, and a nitride oxide of silicon as well as an oxide, a nitride, and a nitride oxide of aluminum are preferable.

Examples of the oxide of silicon may include SiOx. Herein, x is preferably 1.4<x<2.0, from the viewpoint of achieving a balance between transparency and water vapor barrier properties of the inorganic barrier layer. Another example of the oxide of silicon may be SiOC.

Examples of the nitride of silicon may include SiNy. Herein, y is preferably 0.5<y<1.5, from the viewpoint of achieving a balance between transparency and water vapor barrier properties of the inorganic barrier layer.

Examples of the nitride oxide of silicon may include SiOpNq. Herein, when the importance is placed on the improvement in adhesion of the inorganic barrier layer, p and q are preferably set to satisfy 1<p<2.0 and 0<q<1.0, such that the inorganic barrier layer is obtained as an oxygen-rich film. Also, when the importance is placed on the improvement in water vapor barrier properties of the inorganic barrier layer, p and q are preferably set to satisfy 0<p<0.8 and 0.8<q<1.3, such that the inorganic barrier layer is obtained as a nitrogen-rich film.

Examples of the oxide, nitride and nitride oxide of aluminum may include AlOx, AlNy, and AlOpNq. Among these, from the viewpoint of inorganic barrier properties, SiOpNq and AlOx as well as a mixture thereof are particularly preferable.

Examples of the method for forming the inorganic barrier layer may include a vapor deposition method, a sputtering method, an ion plating method, an ion beam assisted vapor deposition method, an arc discharge plasma vapor deposition method, a thermal CVD method, and a plasma CVD method.

In the example of FIG. 1, the inorganic barrier layer 140 extends, in addition to on the top surface 130U of the organic barrier layer 130, in a peripheral region 140P. As a result, the side area 120S of the conductor layer 120 is also sealed by a combination of the organic barrier layer 130 and the inorganic barrier layer 140. Since the organic barrier layer 130 achieves favorable sealing without any gaps, the inorganic barrier layer 140 stacked thereon can also achieve favorable sealing by the combination with the organic barrier layer 130. As a result, the obtained device structure body can have, for example, the effect of reducing the occurrence of failures in the outer circumferential area of the display region. Also, since the width of the peripheral region 140P of the inorganic barrier layer 140 is larger than that of the peripheral region 130P of the organic barrier layer 130, sealing in the side area of the organic barrier layer 130 is further reliably achieved, which leads to the achievement of further favorable sealing.

The thickness of the inorganic barrier layer is preferably 1 nm or more, more preferably 5 nm or more, and further preferably 10 nm or more, and is preferably 500 nm or less, more preferably 200 nm or less, and further preferably 100 nm or less. When the thickness of the inorganic barrier layer is equal to or more than the aforementioned lower limit value, effective suppression of the intrusion of moisture can be easily achieved. When the thickness of the inorganic barrier layer is equal to or less than the aforementioned upper limit value, advantageous effects of, for example, reduction in the thickness of the device structure body, reduction in the production cost, and shortening of the duration for production can be achieved.

[9.4. Optional Step, Variation Examples, and Others]

The method for producing a device structure body according to the present invention may include, in addition to the steps (1) to (3), an optional step. Examples of such an optional step may include a step of disposing an optional component on the top surface of the inorganic barrier layer. Specifically, as illustrated in FIG. 1, the circular polarizing plate 160 may be disposed on the top surface of the inorganic barrier layer 140 through the adhesive layer 150 to produce a device structure body including a circular polarizing plate.

In the example illustrated in FIG. 1, the steps (1) to (3) were each performed only once. However, the present invention is not limited thereto. For example, after the completion of the steps (1) to (3), a series of the steps (1) to (3) may be further performed once or more, so that two or more sets of combinations of the organic barrier layer and the inorganic barrier layer are stacked on each other.

In the example illustrated in FIG. 1, the structure body having the schematic structure of an organic electroluminescent display device has been presented. However, the present invention is not limited thereto.

For example, a device structure body including, as the conductor layer, a layer of an electroconductive material having a thin line-shape pattern disposed on a substrate may be produced. As such an electroconductive material, a metal material such as ITO or silver nanowire may be adopted. Also, when a highly flexible film such as a resin film is used as the substrate in this case, the entire device structure body can be highly flexible as a result of the high flexibility of the organic barrier layer. Such a device structure body can be usefully used as a component of a flexible touch sensor. As the resin film as such a substrate, a general-purpose film such as a PET (polyethylene terephthalate) film, a resin film containing an alicyclic structure-containing polymer (for example, trade name “ZEONOR”, manufactured by ZEON Corporation), or the like may be used. With such a film having high durability to a nonpolar solvent, a device structure body having high quality and high flexibility can be easily manufactured by the production method according to the present invention.

### EXAMPLES

Hereinafter, the present invention will be specifically described by illustrating examples. However, the present invention is not limited to the following examples, and may be freely modified for implementation without departing from the scope of claims of the present invention and the scope of their equivalents. In the following description, “%” and “part” representing quantity are on the basis of weight, unless otherwise specified.

[Evaluation Methods]

[Young's Modulus, Tensile Elongation, and tan δ of Resin]

The Young's modulus and tensile elongation at 23° C. of a resin were measured in accordance with JIS K7113. The loss tangent tan δ (loss modulus/storage modulus) at 40° C. or higher and 200° C. or lower of a resin was measured by shaping the resin into a film, cutting the film into a test sample of 10 mm in width×20 mm in length, and using a DMS6100 dynamic viscoelasticity measuring device manufactured by Hitachi High-Tech Science Corporation.

[Production Example 1]

(P1-1. Production of Hydrogenated Block Copolymer)

Using styrene as an aromatic vinyl compound and isoprene as a chain conjugated diene compound, production of a hydrogenated product of a block copolymer (hydrogenated block copolymer) having a triblock structure, in which polymer blocks [A] were bonded to both ends of a polymer block [B], was performed by the following procedure.

Into a reaction vessel equipped with a stirrer, inside which the atmosphere was sufficiently substituted with nitrogen, 256 parts of dehydrated cyclohexane, 25.0 parts of dehydrated styrene, and 0.615 part of n-dibutyl ether were charged. While the mixture was stirred at 60° C., 1.35 parts of n-butyl lithium (a 15% cyclohexane solution) was added to initiate polymerization. The mixture was reacted under stirring at 60° C. for 60 minutes. The polymerization conversion ratio at this point was 99.5%

(The polymerization conversion ratio was measured by gas chromatography. The same applies hereinafter.).

Subsequently, 50.0 parts of dehydrated isoprene was added, and the mixture was continuously stirred at the same temperature for 30 minutes. The polymerization conversion ratio at this point was 99%.

After that, 25.0 parts of dehydrated styrene was further added, and the mixture was stirred at the same temperature for 60 minutes. The polymerization conversion ratio at this point was almost 100%.

Subsequently, 0.5 part of isopropyl alcohol was added to the reaction liquid to terminate the reaction, thereby obtaining a solution (i) containing a block copolymer.

The weight-average molecular weight (Mw) of the block copolymer in the obtained solution (i) was 44,900, and the molecular weight distribution (Mw/Mn) (measured as a polystyrene equivalent value by gel permeation chromatography using tetrahydrofuran as a solvent; the same applies hereinafter) thereof was 1.03.

Subsequently, the solution (i) was transferred into a pressure resistant reaction vessel equipped with a stirrer. To the solution (i), 4.0 parts of a silica-alumina carried nickel catalyst (E22U, nickel carried amount 60%; manufactured by Nikki Chemicals Co.) as a hydrogenation catalyst and 350 parts of dehydrated cyclohexane were added and mixed. The block copolymer was hydrogenated by substituting the inside of the reaction vessel with hydrogen gas and further supplying hydrogen while stirring the solution to perform a hydrogenation reaction at a temperature of 170° C. and a pressure of 4.5 MPa for 6 hours, thereby obtaining a solution (iii) containing a hydrogenated product (ii) of the block copolymer. The weight-average molecular weight (Mw) of the hydrogenated product (ii) in the solution (iii) was 45,100, and the molecular weight distribution (Mw/Mn) thereof was 1.04.

After the termination of the hydrogenation reaction, the solution (iii) was filtered to remove the hydrogenation catalyst. After that, to the filtered solution (iii), 1.0 part of a xylene solution, in which 0.1 part of a phosphorus-based antioxidant was dissolved, was added and dissolved to obtain a solution (iv). The phosphorus-based antioxidant was 6-[3-(3-t-butyl-4-hydroxy-5-methylphenyl)propoxy]-2,4,8,10-tetrakis-t-butyldibenzo[d,f][1.3.2]dioxaphosphepin (“SUMILIZER® GP” manufactured by Sumitomo Chemical Company, Limited; hereinafter, referred to as an “antioxidant A”).

Subsequently, the solution (iv) was filtered through a 30H Zeta Plus (registered trademark) filter (manufactured by Cuno, Inc., pore diameter 0.5 μm to 1 μm), and successively filtered through another metal fiber filter (pore diameter 0.4 manufactured by Nichidai Corporation) to remove minute solid content. From the filtered solution (iv), the solvent cyclohexane and xylene as well as other volatile components were removed at a temperature of 260° C. and a pressure of 0.001 MPa or less, using a cylindrical concentration dryer (product name

“Kontro”, manufactured by Hitachi, Ltd.). Then, the solid content in a molten state was extruded from the aforementioned concentration dryer through a die directly connected thereto to be in a form of strand shape. The extruded product was cooled and then cut by a pelletizer to obtain 85 parts of pellets (v) containing the hydrogenated product of the block copolymer and the antioxidant A. The weight-average molecular weight (Mw) of the hydrogenated product of the block copolymer (hydrogenated block copolymer) in the obtained pellets (v) was 45,000, and the molecular weight distribution (Mw/Mn) thereof was 1.08. The hydrogenation rate measured by ¹H-NMR was 99.9%.

(P1-2. Production of Silane Modified Product of Hydrogenated Block Copolymer)

To 100 parts of the pellets (v) obtained in (P1-1), 2.0 parts of vinyltrimethoxysilane and 0.2 part of di-t-butyl peroxide were added to obtain a mixture. This mixture was kneaded in a biaxial extruder at a barrel temperature of 210° C. for a retention time of 80 seconds to 90 seconds. The kneaded mixture was extruded and then cut by a pelletizer to obtain pellets (vi) of the silane modified product of the hydrogenated block copolymer. From the pellets (vi), a film-shaped test piece was prepared for evaluation of the glass transition temperature Tg by the tano peak of the dynamic viscoelasticity measuring device. The evaluation result was 124° C. The peak value of tan δ at 40° C. or higher and 200° C. or lower of the pellets (vi) was 1.3. The Young's modulus at 23° C. of the pellets (vi) was 0.5 GPa, and the tensile elongation thereof was 550%. A refractive index (n1) of the pellets (vi) measured by an Abbe refractometer was 1.50.

### Example 1

(1-1. Hygroscopic Particle Dispersion Liquid)

In a bead mill, 10 g of zeolite particles (refractive index 1.5) containing primary particles having a number-average particle diameter of 50 nm, 4 g of a dispersant having a basic adsorptive group (hydroxyl group-containing carboxylic acid ester, trade name “DISPERBYK108”, manufactured by BYK-Chemie), and 46 g of cyclohexane were mixed and dispersed. By this operation, a 17% zeolite dispersion liquid 1 was prepared.

(1-2. Polymer Solution)

In 60 g of cyclohexane, 28 g of the pellets (vi) obtained in Production Example 1 and 12 g of a plasticizer (a plasticizer containing an aliphatic hydrocarbon polymer, product name: Nisseki Polybutene LV-100, manufactured by Nippon Oil Corporation, refractive index 1.50, number-average molecular weight 500; the same applies hereinafter) were mixed and dissolved. By this operation, a polymer solution 1 with a solid content of 40% was prepared.

(1-3. Resin Solution for Printing)

60 g of the zeolite dispersion liquid 1 obtained in (1-1) and 100 g of the polymer solution 1 obtained in (1-2) were mixed. Accordingly, a resin solution for printing 1 was obtained.

The viscosity of the obtained resin solution for printing 1 was measured. The viscosity was measured using an SV-10 tuning-fork vibration type viscometer manufactured by A&D Company, Limited. The measurement was performed by filling a sample container with the resin solution such that the liquid surface comes to be within reference lines and then placing a vibrator to a predetermined position in the resin solution. The measurement was performed under an environment of 25° C.±2° C. As a result, the viscosity of the resin solution for printing 1 was found to be 400 cP.

(1-4. Production of Device Structure Body)

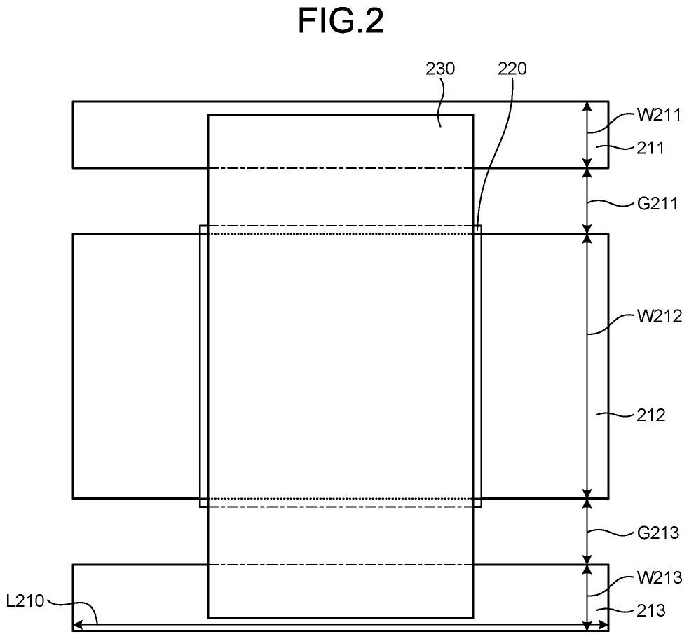

As a device structure body for the evaluation of the resin solution for printing, an organic electroluminescent light-emitting device having a structure schematically illustrated in FIG. 2 to FIG. 4 was produced. FIG. 2 to FIG. 4 are top views illustrating a planar shape and layout of each layer in the present example. Such a light-emitting device was produced by, as illustrated in FIG. 2 to FIG. 4, forming, on a glass substrate (not illustrated for convenience of illustration of other members), transparent electrode layers 211 to 213, a conductor layer 220, a reflective electrode layer 230, an organic barrier layer 240, and an inorganic barrier layer 250 in this order.

The conductor layer 220 included a hole transport layer, a yellow light-emitting layer, an electron transport layer, and an electron injection layer. The details of the production steps are as follows.

(1-4-1. Multilayer Product)

First, a glass substrate of 40 mm in length×40 mm in width was prepared. On the glass substrate, transparent electrode layers 211 to 213 having a thickness of 100 nm, a hole transport layer having a thickness of 10 nm, a yellow light-emitting layer having a thickness of 20 nm, an electron transport layer having a thickness of 15 nm, an electron injection layer having a thickness of 1 nm, and a reflective electrode layer 230 having a thickness of 100 nm were formed in this order.

Each layer from the hole transport layer to the electron transport layer was formed with an organic material. The material of each layer from the transparent electrode layers to the reflective electrode layer was as follows.

Transparent electrode layers; tin-doped indium oxide (ITO)

Hole transport layer; 4,4′-bis[N-(naphthyl)-N-phenylamino]biphenyl (α-NPD)

Yellow light-emitting layer; α-NPD doped with 1.5% by weight of rubrene

Electron transport layer; phenanthroline derivative (BCP)

Electron injection layer; lithium fluoride (LiF)

Reflective electrode layer; Al

The transparent electrode layers were formed by a reactive sputtering method with an ITO target.

Each layer from the hole transport layer to the reflective electrode layer was formed by disposing in a vacuum deposition device a substrate on which the transparent electrode layers had already been formed, and then sequentially vapor depositing the aforementioned materials from the hole transport layer to the reflective electrode layer by resistance heating.

As illustrated in FIG. 2, the transparent electrode layers 211 to 213 had a rectangular shape and were spaced apart from each other in parallel. The edges of the transparent electrode layers 211 to 213 were parallel to the edges of the glass substrate. The length (a length indicated by arrow L210) of each of the transparent electrode layers 211 to 213 was 40 mm. A width W211 of the transparent electrode layer 211 and a width W213 of the transparent electrode layer 213 were each 5 mm. A width W212 of the transparent electrode layer 212 was 20 mm. Widths G211 and G213 of gaps between the transparent electrode layers were each 5 mm.

The conductor layer 220 had a square shape illustrated in FIG. 2. The edges of the conductor layer 220 were parallel to the edges of the glass substrate. The center thereof was aligned with the center of the glass substrate. The width of one edge of the conductor layer 220 was 21 mm. Layers constituting the conductor layer 220 had the same size.

The reflective electrode layer 230 had a rectangular shape illustrated in FIG. 2. The edges of the reflective electrode layer 230 were parallel to the edges of the glass substrate. The center thereof was aligned with the center of the glass substrate. The size of the reflective electrode 230 was 38 mm×20 mm.

By the aforementioned operation, a multilayer product including the glass substrate, the transparent electrode layers 211 to 213, the conductor layer 220, and the reflective electrode layer 230 was obtained.

(1-4-2. Organic Barrier Layer and Inorganic Barrier Layer)

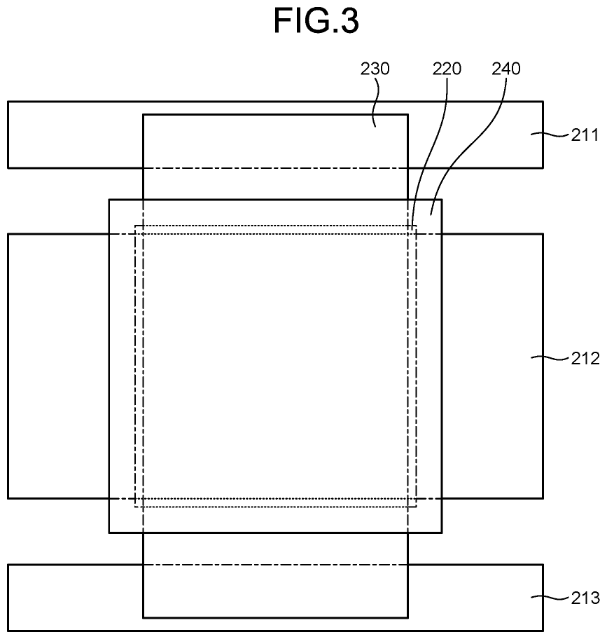

On the multilayer product obtained by the aforementioned operation, the organic barrier layer 240 was formed. The organic barrier layer 240 was formed by forming a layer of the resin solution for printing 1 obtained in (1-3) on the multilayer product by screen printing and then drying the resin solution. The thickness of the organic barrier layer was 4 μm. The organic barrier layer 240 had a square shape illustrated in FIG. 3. The edges of the organic barrier layer 240 were parallel to the edges of the glass substrate. The center thereof was aligned with the center of the glass substrate. The width of one edge of the organic barrier layer 240 was 23 mm. As a result, the organic barrier layer 240 was disposed in a position covering the top surfaces of the conductor layer 220 and the reflective electrode layer 230 and also covering the surroundings of the conductor layer 220 with peripheral regions each having a width of 1 mm.

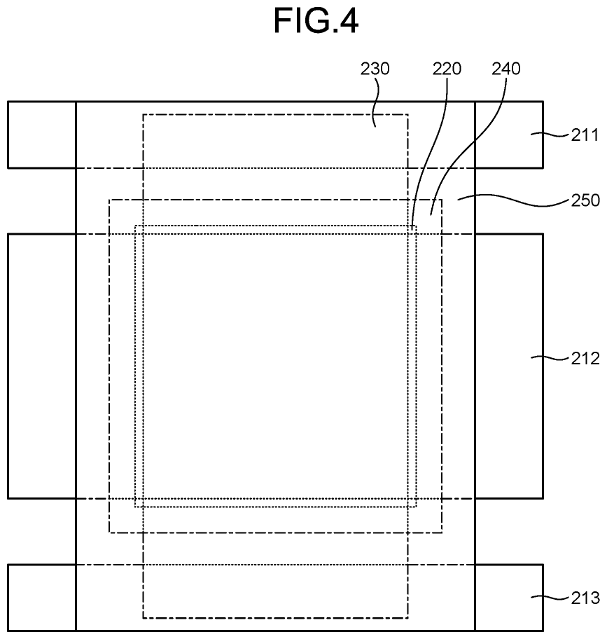

On the top thereof, an SiN film as the inorganic barrier layer 250 was further formed. The inorganic barrier layer 250 was formed by sputtering. The thickness of the inorganic barrier layer 250 was 200 nm. The inorganic barrier layer 250 had a rectangular shape illustrated in FIG. 4. The edges of the inorganic barrier layer 250 were parallel to the edges of the glass substrate. The center thereof was aligned with the center of the glass substrate. The size of the inorganic barrier layer 250 was 30 mm×40 mm. Accordingly, a device structure body having the respective layers placed as illustrated in FIG. 4 was obtained.

(1-5. Evaluation of Device Structure Body)

The device structure body obtained in (1-4-2) was stored under an environment of 60° C. and 90% RH for 300 hours. After the end of the storage period, the device structure body was energized through the transparent electrode layers 211 to 213 for emitting light. The light emitting state was observed. As a result, the light emitting state was favorable without occurrence of dark sports or the like.

### Example 2

(2-1. Hygroscopic Particle Dispersion Liquid)

In a bead mill, 10 g of zeolite particles (refractive index 1.5) containing primary particles having a number-average particle diameter of 50 nm, 4 g of a dispersant having a basic adsorptive group (hydroxyl group-containing carboxylic acid ester, trade name “DISPERBYK108”, manufactured by BYK-Chemie), and 46 g of ethylcyclohexane were mixed and dispersed. By this operation, a 17% zeolite dispersion liquid 2 was prepared.

(2-2. Polymer Solution)

In 60 g of ethylcyclohexane, 28 g of the pellets (vi) obtained in Production Example 1 and 12 g of a plasticizer (a plasticizer containing an aliphatic hydrocarbon polymer, product name: Nisseki Polybutene LV-100, manufactured by Nippon Oil Corporation, refractive index 1.50, number-average molecular weight 500; the same applies hereinafter) were mixed and dissolved. By this operation, a polymer solution 2 with a solid content of 40% was prepared.

(2-3. Resin Solution for Printing 2)

60 g of the zeolite dispersion liquid 2 obtained in (2-1), 100 g of the polymer solution 2 obtained in (2-2), and further 240 g of ethylcyclohexane were mixed.

Accordingly, a resin solution for printing 2 was obtained.

The viscosity of the obtained resin solution for printing 2 was measured. The viscosity was measured using the SV-10 tuning-fork vibration type viscometer manufactured by A&D Company, Limited. The measurement was performed by filling a sample container with the resin solution such that the liquid surface comes to be within reference lines and then placing a vibrator to a predetermined position in the resin solution. The measurement was performed under an environment of 25° C.±2° C. As a result, the viscosity of the resin solution for printing 2 was found to be 8 cP.

(2-4. Production of Device Structure Body)

An organic electroluminescent light-emitting device having a structure schematically illustrated in FIG. 2 to FIG. 4 was produced by the same operations as those of (1-4) of Example 1 except for the following change points.

The resin solution for printing 2 obtained in (2-3) was used instead of the resin solution for printing 1 obtained in (1-3).

Inkjet printing was performed as the printing method instead of the screen printing. The thickness of the organic barrier layer was 2 μm.

(2-5. Evaluation of Device Structure Body)

The device structure body obtained in (2-4) was stored under an environment of 60° C. and 90% RH for 300 hours. After the end of the storage period, the device structure body was energized through the transparent electrode layers 211 to 213 for emitting light. The light emitting state was observed. As a result, the light emitting state was favorable without occurrence of dark sports or the like.

### Comparative Example 1

A substrate film made of a cycloolefin polymer having a thickness of 50 μm was prepared. On the substrate film, an SiN film as an inorganic barrier layer was formed by sputtering. The conditions for the sputtering were the same as those for the formation of the inorganic barrier layer 250 in Example 1. The thickness of the inorganic barrier layer was 200 nm. Accordingly, a barrier film 1 having a layer structure of (substrate film)/(inorganic barrier layer) was obtained. The water vapor transmission rate of the barrier film was 10⁻3/m²·day.

The resin solution for printing 1 obtained in (1-3) of Example 1 was applied onto the inorganic barrier layer of the barrier film 1 with an applicator to form a layer of the resin solution for printing. The layer formed was dried to form an organic barrier layer having a thickness of 4 Accordingly, a layered body 1 having a layer structure of (substrate film)/(inorganic barrier layer)/(organic barrier layer) was obtained.

The layered body 1 was cut to have a 23 mm×40 mm rectangular shape. The rectangular layered body 1 was laminated to the multilayer product obtained in (1-4-1) of Example 1. For laminating, a vacuum laminator was used, and the layered body 1 was heated to 90° C. Upon the lamination, the organic barrier layer side of the layered body 1 was set on the lower side (that is, a side to be in contact with the reflective electrode layer 230 or the like of the multilayer product). The edges of the layered body 1 were parallel to the edges of the glass substrate. The center thereof was aligned with the center of the glass substrate. As a result, the layered body 1 was disposed in a position covering the top surfaces of the conductor layer 220 and the reflective electrode layer 230 and also covering two edges on the surroundings of the conductor layer 220 with peripheral regions each having a width of 1 mm. Accordingly, a device structure body was obtained.

The obtained device structure body was evaluated by the same manner as that in (1-5) of Example 1. As a result, the outer circumferential area of the light-emitting layer was partly quenched, and many small dark spots were observed in the outer circumferential area.

### REFERENCE SIGN LIST

100: device structure body

110: multilayer product

111: substrate

111U: top surface of substrate

120: conductor layer

120S: side area of conductor layer

120U: top surface of conductor layer

121: reflective electrode layer

122: light-emitting layer

123: transparent electrode

130: organic barrier layer

130P: peripheral region

130U: top surface of organic barrier layer

140: inorganic barrier layer

140P: peripheral region

140U: top surface of inorganic barrier layer

150: adhesive layer

160: circular polarizing plate

211: transparent electrode layer

212: transparent electrode layer

213: transparent electrode layer

220: conductor layer

230: reflective electrode layer

240: organic barrier layer

250: inorganic barrier layer

G211: Width of gap between the transparent electrode layers

G213: Width of gap between the transparent electrode layers

L210: length of transparent electrode layer

W211: width of transparent electrode layer

W212: width of transparent electrode layer

W213: width of transparent electrode layer

1. A resin solution for printing comprising:
a nonpolar solvent; and
a thermoplastic elastomer having a silicon atom-containing polar group, the thermoplastic elastomer being dissolved in the nonpolar solvent, wherein
the resin solution has a viscosity of 1 cP or higher and 5000 cP or lower.

2. The resin solution for printing according to claim 1, wherein the viscosity is 1 cP or higher and 1000 cP or lower.

3. The resin solution for printing according to claim 1, wherein the thermoplastic elastomer is a hydrogenated aromatic vinyl compound-conjugated diene copolymer.

4. The resin solution for printing according to claim 1, further comprising a hygroscopic particle.

5. The resin solution for printing according to claim 1, further comprising a dispersant dissolved in the nonpolar solvent.

6. A method for producing a device structure body comprising:
forming, by printing, a layer of the resin solution for printing according to claim 1 on a multilayer product including a substrate and a conductor layer disposed on a surface of the substrate;
drying the layer of the resin solution for printing to form an organic barrier layer; and
forming an inorganic barrier layer on a top surface side of the organic barrier layer.

7. The method for producing a device structure body according to claim 6, wherein the inorganic barrier layer is a layer made of a material containing a silicon atom or an aluminum atom.
